(19) United States
(12) Patent Application Publication
(10) Pub. No.: US 2015/0070599 A1
(43) Pub. Date: Mar. 12, 2015

(54) Substrate Sheet and Touch Panel

(71) Applicant: POLYMATECH JAPAN CO., LTD., Saitama (JP)

(72) Inventors: Shinichi Tomooka, Tokyo (JP); Soyoko Nikki, Tokyo (JP); Yutaka Nakanishi, Tokyo (JP)

(73) Assignee: POLYMATECH JAPAN CO., LTD., Saitama (JP)

(21) Appl. No.: 14/394,594

(22) PCT Filed: Jun. 7, 2013
(86) PCT No.: PCT/JP2013/065828

§ 371 Date: Oct. 15, 2014

(30) Foreign Application Priority Data
Jun. 14, 2012 (JP) 2012-134381

(51) Int. Cl. G06F 3/044; H05K 1/09; H05K 1/02

(52) U.S. Cl. CPC G06F 3/044; H05K 1/0274; H05K 1/092
USPC 349/12; 174/251

(57) ABSTRACT

For a substrate sheet having a transparent electrode made of an electroconductive polymer and metal wiring connecting this transparent electrode and a connector junction on a translucent base and provided with a protective layer covering the transparent electrode and the metal wiring, a substrate sheet is provided that has its transparent electrode protected and its metal wiring protected from corrosion. The protective layer was made up of a laminate having a sulfuration-resistant resist layer that prevents the metal wiring from being sulfurated and a lightfast resist layer that absorbs ultraviolet light stacked on the base, and the sulfuration-resistant resist layer was a polyurethane-polyurea-based plastic layer.

### TECHNICAL FIELD

The present invention relates to a substrate sheet that can be used as an electrostatic sensor or any similar unit of devices such as a touch panel, and also to a touch panel in which this substrate sheet is used.

### BACKGROUND ART

An electrode of an electrostatic sensor for devices such as a touch panel is made of a transparent electroconductive polymer. Since this transparent electroconductive polymer gets seriously damaged when exposed to light, this electrode is covered with a protective layer that is a resist coating containing an ultraviolet absorber. Such technologies are described in, for example, Japanese Unexamined Patent Application Publication No. 2011-192150 (PTL 1).

### CITATION LIST

### Patent Literature

PTL 1: Japanese Unexamined Patent Application Publication No. 2011-192150

### SUMMARY OF INVENTION

### Technical Problem

A metal wiring section for connecting the electrode and external equipment is free of the lightfastness issue observed with an electroconductive polymer, but disadvantageously can lose electroconductivity through reaction with a sulfur component.

Thus an object of the present invention is to provide a substrate sheet that has not only its electroconductive polymer protected but also its metal wiring section protected from corrosion, and a touch panel formed using this substrate sheet.

### Solution to Problem

To achieve this object, the inventors provide a substrate sheet described below.

A substrate sheet has a transparent electrode made of an electroconductive polymer and metal wiring on a translucent base, the metal wiring connecting the transparent electrode and a connector junction, and is provided with a protective layer covering the transparent electrode and the metal wiring. The protective layer is made up of a laminate having a sulfuration-resistant resist layer configured to prevent the metal wiring from being sulfurated and a lightfast resist layer configured to absorb ultraviolet radiation stacked in this order from the translucent base side. The sulfuration-resistant resist layer is a polyurethane-polyurea-based plastic layer.

For a substrate sheet having a transparent electrode made of an electroconductive polymer and metal wiring, providing a protective layer made up of a laminate having a sulfuration-resistant resist layer configured to prevent the metal wiring from being sulfurated and a lightfast resist layer configured to absorb ultraviolet radiation stacked in this order from the translucent base side prevents the transparent electrode from being damaged by ultraviolet radiation and the metal wiring from being sulfurated.

Furthermore, the use of a polyurethane-polyurea-based plastic layer as the sulfuration-resistant resist layer leads to improved gas-barrier properties owing to the presence of a polyurea component, thereby effectively preventing the metal wiring from being sulfurated.

The substrate sheet can be one in which the polyurethane-polyurea-based plastic forming the polyurethane-polyurea-based plastic layer is a plastic containing urea bonds in addition to urethane bonds as a result of being cured containing a polyisocyanate component in 1.2 to 5.5 times the amount of the polyisocyanate component that would have NCO groups stoichiometric with respect to the OH groups of a polyol component.

The use of a plastic having urethane bonds and urea bonds as a result of being cured containing a polyisocyanate component in 1.2 to 5.5 times the amount of the polyisocyanate component that would have NCO groups stoichiometric with respect to the OH groups of a polyol component as the polyurethane-polyurea-based plastic forming the polyurethane-polyurea-based plastic layer protects the metal wiring from sulfuration.

The polyurethane-polyurea-based plastic forming the polyurethane-polyurea-based plastic layer can be a plastic that is a product of the reaction and curing of a raw material with which the NCO group/OH group value will be in the range of 1.2 to 5.5.

The use of a plastic that is a product of the reaction and curing of a raw material with which the NCO group/OH group value will be in the range of 1.2 to 5.5 as the polyurethane-polyurea-based plastic forming the polyurethane-polyurea-based plastic layer leads to a polyurethane-polyurea-based layer being formed rich in an isocyanate component and has urea bonds in addition to urethane bonds. As a result, the crosslinking density of the plastic is higher than in the case where no urea bonds are formed. In other words, the distance between molecular chains is closed. This helps to prevent the infiltration of any sulfur component, thereby protecting the metal wiring from sulfuration-related damage. As a result, the protective layer has excellent sulfuration resistance.

The sulfuration-resistant resist layer can be a plastic layer having a crosslinking density higher than that of the lightfast resist layer. Ensuring that the sulfuration-resistant resist layer has a crosslinking density higher than that of the lightfast resist layer leads to enhanced sulfuration resistance.

The substrate sheet can be one in which the lightfast resist layer is a polyurethane-based plastic layer. The use of a polyurethane-based plastic layer as the lightfast resist layer leads to enhanced adhesion to the sulfuration-resistant resist layer.

Furthermore, a touch panel can be produced using this substrate sheet. Having a substrate sheet described above, this touch panel is unlikely to undergo alterations in the nature of an electrode or experience damage to metal wiring.

### Advantageous Effects of Invention

According to a substrate sheet and a touch panel according to the present invention, a transparent electrode made of an electroconductive polymer and metal wiring can be protected from damage and sulfuration caused by ultraviolet radiation and a sulfur component.

### BRIEF DESCRIPTION OF DRAWINGS

FIG. 1 is a plan view of a substrate sheet.

FIG. 2 is a cross-sectional view of FIG. 1 taken along line SA-SA.

### DESCRIPTION OF EMBODIMENTS

The following describes the present invention in more detail on the basis of an embodiment.

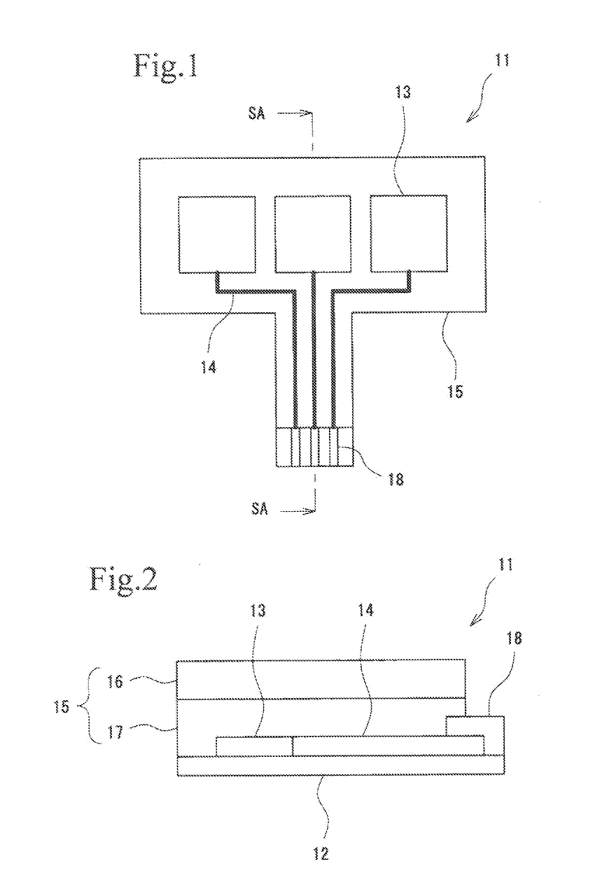

A substrate sheet 11 according to this embodiment has, as illustrated in FIGS. 1 and 2, a layer structure including at least a base 12 transparent to light, a transparent electrode 13 made of a transparent electroconductive polymer on the base 12, metal wiring 14 for connecting the transparent electrode 13 and an external electric circuit, and a protective layer 15 covering the transparent electrode 13 and the metal wiring 14. This substrate sheet can be used as a capacitive touch panel.

The base 12 is a highly transparent plastic film and can be made from, for example, a polyethylene terephthalate (PET) resin, a polyethylene naphthalate (PEN) resin, a polycarbonate (PC) resin, a methacrylic (PMMA) resin, a polypropylene (PP) resin, a polyurethane (PU) resin, a polyamide (PA) resin, a polyethersulfone (PES) resin, a polyether ether ketone (PEEK) resin, a triacetyl cellulose (TAC) resin, or a cycloolefin polymer (COP).

The base 12 may be surface-treated with a layer such as a primer layer that enhances adhesion to the electroconductive polymer, a surface-protecting layer, or an overcoat layer for antistatic and other purposes.

The electroconductive polymer to serve as the transparent electrode 13 is made of an electroconductive polymer from which a transparent layer can be formed. Examples of such transparent electroconductive polymers include polyparaphenylene, polyacetylene, and PEDOT-PSS (poly-3,4-ethylenedioxythiophene-polystyrene sulfonic acid).

A sulfuration-resistant resist layer 17 and a lightfast resist layer 16 both have a high transmittance to light in the visible spectrum, and these layers are transparent or almost transparent. The lightfast resist layer 17 has an almost zero transmittance to light in the ultraviolet spectrum (wavelengths less than 400 nm) to block ultraviolet radiation.

The metal wiring 14 is wiring that connects the transparent electrode 13 and a connector junction 18 that is to be connected to an electric circuit disposed outside this substrate sheet 11, such as a data processing unit (not illustrated).

The material for the metal wiring 14 is preferably, for example, an electroconductive paste or electroconductive ink that contains a highly electroconductive metal, such as copper, aluminum, silver, or an alloy containing these metals. It is preferred to use silver wiring because silver has high electroconductivity when compared among such metals and alloys and is less oxidizable than copper.

The protective layer 15 is a layer covering the transparent electrode 13 and the metal wiring 14, and is a layer that is a stack of a lightfast resist layer 16 and a sulfuration-resistant resist layer 17. This protective layer is formed by covering the transparent electrode 13 and the metal wiring 14 with a sulfuration-resistant resist layer 17 and covering this sulfuration-resistant resist layer 17 with a lightfast resist layer 16.

The lightfast resist layer 16 is a layer for protecting the substrate sheet 11 from damage such as scratches and protecting the transparent electroconductive polymer from ultraviolet radiation, and is a layer of a transparent plastic containing an ultraviolet absorber. A hard plastic is selected for use as the transparent plastic, and examples of plastics that can be used include acrylic, urethane, epoxy, and polyolefin-based plastics as well as other plastics. Preferably, this layer is a polyurethane-based plastic layer that is a cured form of a raw-material composition made up containing a polyisocyanate component and a polyol component, because this ensures easy control of hardness and high strength.

When this layer is a polyurethane-based plastic layer, it is particularly preferred, in light of weather resistance including yellowing, to use an aliphatic diisocyanate, an alicyclic polyisocyanate, and an arylaliphatic polyisocyanate as the polyisocyanate component in the raw-material composition. More specifically, polyisocyanates that can be used include the following: hexamethylene diisocyanate as an example of an aliphatic diisocyanate; dicyclohexylmethane diisocyanate, cyclohexyl diisocyanate, and isophorone diisocyanate as examples of alicyclic polyisocyanates; xylylene diisocyanate as an example of an arylaliphatic polyisocyanate; and adduct-type, buret-type, isocyanurate-type, and urethane imine-type polyisocyanates derived from the foregoing polyisocyanates.

The following can also be used: aromatic polyisocyanates such as 2,4-tolylene diisocyanate, 2,6-tolylene diisocyanate, 4,4′-diphenylmethane diisocyanate, 2,4′-diphenylmethane diisocyanate, and para-phenylene diisocyanate; and adduct-type, buret-type, isocyanurate-type, and urethane imine-type polyisocyanates derived from these aromatic polyisocyanates.

Examples of polyol components include the following: low-molecular-weight polyols such as ethylene glycol, propylene glycol, and glycerol; polyether polyols obtained by adding an alkylene oxide, such as diethylene oxide, propylene oxide, 1,2-butadiene oxide, or styrene oxide, to a polyphenol; and polyester polyols obtained through dehydration condensation reaction between a low-molecular-weight polyol mentioned above and a dicarboxylic acid, such as adipic acid or phthalic acid.

Other examples include acrylic polyols, polycarbonate polyols, polyurethane polyols, and polycaprolactone polyols.

The lightfast resist layer 16 contains an ultraviolet absorber. A wide variety of ultraviolet absorbers can be used as this ultraviolet absorber, including salicylic-acid-based ones, benzophenone-based ones, benzotriazole-based ones, and hindered-amine-based ones.

The average transmittance of the lightfast resist layer 16 to light in a visible spectrum of 400 nm to 800 nm is preferably 80% or more, more preferably 85% or more.

The thickness of the lightfast resist layer 16 is usually in the range of 3 μm to 10 μm, preferably 6 μm to 8 μm. This is because too large a thickness makes this layer of poor flexibility, and too small a thickness weakens the effect of lightfastness.

The sulfuration-resistant resist layer 17 is a layer mainly for preventing the metal wiring 14 from being sulfurated and is a polyurethane-polyurea-based plastic layer. The polyurethane-polyurea-based plastic forming the polyurethane-polyurea-based plastic layer is a plastic cured containing a polyisocyanate component more than the amount of the polyisocyanate component that would have NCO groups stoichiometric with respect to the OH groups of a polyol component.

The use of a raw material containing a polyisocyanate component more than stoichiometric with respect to a polyol component leads to an excess of NCO groups, other than the NCO groups that form urethane bonds, reacting with water and then with other NCO groups to form urea bonds. The polyurethane-polyurea-based plastic is therefore a plastic having urea bonds in addition to urethane bonds, and is a plastic having a cross-linking density higher than that of polyurethane-based plastics that simply have urethane bonds.

The raw material of a polyurethane-polyurea-based plastic containing a polyol component and a polyisocyanate component preferably contains the polyisocyanate component in 1.2 to 5.5 times the amount of the polyisocyanate component that would have NCO groups stoichiometric with respect to the OH groups of the polyol component. An amount less than 1.2 times results in a reduced proportion of urea bonds and thus insufficient sulfuration resistance. An amount more than 5.5 times often makes the sulfuration-resistant resist layer 17 stiff and brittle because of a large number of urea bonds.

Polyurethane-polyurea-based plastics include plastics in all of the following states: (a) copolymers in which a polyurethane polymer and a polyurea polymer are in connection with each other, (b) mixtures in which a polyurethane polymer and a polyurea polymer exist independently of one another, and mixtures in which (a) and (b) are mixed.

When the lightfast resist layer 16 is made of a polyurethane-based plastic, it is possible to use the same components as the polyisocyanate component and the polyol component in the raw material composition for the lightfast resist layer 16, and the sulfuration-resistant resist layer 17 can be formed by changing the proportion of the polyisocyanate component in the composition. As a result, the lightfast resist layer 16 and the sulfuration-resistant resist layer 17 strongly adhere together, leading to more effective protection of the transparent electrode 13 and the metal wiring 14.

Furthermore, stacking the sulfuration-resistant resist layer 17 directly on the metal wiring 14 ensures that any sulfur component that could reach the metal wiring 14 through any other layer is reliably prevented from infiltrating.

The average transmittance of the sulfuration-resistant resist layer 17 to light in a visible spectrum of 400 nm to 800 nm is preferably 80% or more, more preferably 85% or more.

The thickness of the sulfuration-resistant resist layer 17 is usually in the range of 3 μm to 10 μm, preferably 6 μm to 8 μm. This is because any thickness exceeding 10 μm makes this layer of poor flexibility, any thickness smaller than 3 μm weakens the effect of sulfuration resistance, and a thickness of 6 μm to 8 μm gives this layer flexibility and high resistance to sulfuration.

The use of a stack of a lightfast resist layer 16 and a sulfuration-resistant resist layer 17 as a protective layer 15 in this way provides the following advantages.

For example, forming the protective layer 15 as a single lightfast and sulfuration-resistant layer having a thickness similar to that obtained in the case of two layers according to the present invention would require that the isocyanate component be contained in an amount larger than in the case of two layers so that more urea bonds should be contained. This is because if the isocyanate component is contained in the same amount as in the case of two layers, then the crosslinking density of the protective layer is so low that the resistance to sulfuration is poor. If a single layer is used, therefore, it is inevitable that the amount of the polyisocyanate component is larger than in the case of two layers, which causes disadvantages such as the protective layer being stiff. Such a situation also causes increased raw-material costs.

Furthermore, providing the sulfuration-resistant resist layer 17 on the base 12 side and the lightfast resist layer 16 on the outer side is preferable to providing the lightfast resist layer 16 on the base 12 side and the sulfuration-resistant resist layer 17 on the outer side because in the former case sulfur components infiltrating through the lateral sides of the base 12 can be effectively blocked.

Any other layer, other than the layers described above, can be optionally provided. Examples include a coloring layer for coloring the entire sheet and layers for changing the refractive index for light or polarizing light.

For the structure of the substrate sheet 11, it is enough that the transparent electrode 13 and the metal wiring 14 extend on at least a portion of the surface of the base 12, and they may also extend over the entire surface. They may optionally extend on both the front and back surfaces of the base 12.

Furthermore, the shape of components such as the transparent electrode 13 and the metal wiring 14 is not limited to that described above.

To produce the substrate sheet 11, the transparent electrode 13 and the metal wiring 14 are formed through printing in a particular area on a transparent plastic film provided to serve as the base 12. Then raw-material compositions provided to form the sulfuration-resistant resist layer 17 and the lightfast resist layer 16 are individually applied to these components and cured on them to form the protective layer 15. In this way, the substrate sheet 11 is obtained.

### EXAMPLES

Substrate sheets (11) having a layer structure illustrated in FIGS. 1 and 2 were produced.

### Example 1

A transparent electroconductive ink (Orgacon P3000, AGFA) was applied using screen printing to a base (12) made from a transparent PET plastic film to form a rectangular transparent electrode (13). Metal wiring (14) was obtained through screen printing with a silver ink (7145, DuPont) on the base (12). Then on these components a sulfuration-resistant resist layer (17) and a lightfast resist layer (16) were formed one by one.

The sulfuration-resistant resist layer (17) to serve as a lower layer was formed from a raw-material ink obtained by mixing a polyester polyol having a hydroxyl value of 36 mg KOH/g with an HDI-based isocyanate (NCO/OH=2.2), and the lightfast resist layer (16) to serve as an upper layer was formed from a raw-material ink obtained by mixing a polyester polyol and an HDI-based isocyanate (NCO/OH=1.1) and then adding a benzotriazole-based ultraviolet absorber.

The end of the metal wiring (14) was covered with a carbon ink applied through printing, which formed a connector junction (18) to be connected to an electric circuit. The connector junction (18) has an area not covered with the protective layer (15) (the sulfuration-resistant resist layer (17) and the lightfast resist layer (16)) on its surface. In this way, a substrate sheet (11) was obtained in which a transparent electrode (13) and metal wiring (14) were covered with a protective layer (15).

### Examples 2 to 7

Substrate sheets (11) according to Examples 2 to 7 were obtained in the same way as in Example 1 except that the NCO/OH ratio of the sulfuration-resistant resist layer (17) in Example 1 was changed to a value specified in Table 1 below.

### Example 8

A substrate sheet (11) according to Example 8 was produced, in which the order of stacked layers in the protective layer (15) was different from that in Example 1.

In Example 8, a lightfast resist layer (16) was formed as a lower layer, and a sulfuration-resistant resist layer (17) was formed as an upper layer.

TABLE 1

| | | | Example | Example | Example | Example | Example | Example | Example | Example |
|---|---|---|---|---|---|---|---|---|---|---|
| | | | 1 | 2 | 3 | 4 | 5 | 6 | 7 | 8 |
| Sulfuration- | NCO/OH value | | 2.2 | 1.5 | 1.8 | 3.7 | 5.1 | 1.0 | 6.0 | 2.2 |
| resistant | | | | | | | | | | |
| resist layer | | | | | | | | | | |
| Lightfastness | Change in the | 300 | +199% | +190% | +205% | +187% | +184% | +195% | +190% | +176% |
| evaluation | resistance | (h) | | | | | | | | |
| | value of | | | | | | | | | |
| | transparent | | | | | | | | | |
| | electrode | | | | | | | | | |
| Sulfuration | Change in the | 300 | +30% | +61% | +41% | +2% | +20% | (broken) | +5% | +47% |
| resistance | resistance | (h) | | | | | | | | |
| evaluation | value of metal | 500 | +49% | +169% | +73% | +7% | +22% | (broken) | +13% | (broken) |
| | wiring | (h) | | | | | | | | |

| | | | | | | | | |
|---|---|---|---|---|---|---|---|---|
| Percentage change | +23% | +30% | +26% | +20% | +19% | +35% | +25% | +23% |
| in the weight of | | | | | | | | |
| sulfuration-resistant | | | | | | | | |
| resist layer | | | | | | | | |
| (swell test) | | | | | | | | |

### <Methods of Testing and Evaluation of Lightfastness>:

An accelerated lightfastness test according to JIS K7350-4 was performed using a sunshine weather meter (a sunshine carbon arc light source, under 63° C. conditions, no water spraying).

The substrate sheets (11) obtained in Examples 1 to 8 were attached to a white mount and irradiated from the resist surface side for 300 hours, and the percentage change (%) in the resistance value of the transparent electrode (13) was evaluated.

### <Methods of Testing and Evaluation of Sulfuration Resistance>:

The substrate sheets (11) obtained in Examples 1 to 8 were left in a saturated sulfur vapor atmosphere at 85° C. covered with a Petri dish for 300 hours and 500 hours with a powder of sulfur placed around, and the percentage change (%) in the resistance value of the metal wiring (14) was evaluated.

The note “(broken)” in the table means that the value measured by the tester exceeded 2 MΩ, the maximum displayable value.

### <Methods of the Evaluation of Crosslinking Density (a Swell Test)>:

Only a sheet-shaped lightfast resist layer (16) was formed through application in the same way as the formation of the lightfast resist layer (16) of a substrate sheet (11) in Examples 1 to 8, which produced test specimens made up solely of the lightfast resist layer (16) and corresponding to Examples 1 to 8. These test specimens were immersed in toluene for 1 hour, and the changes in weight (%) were recorded in the fields in Table 1 respectively corresponding to Examples 1 to 8.

In Examples 1 to 8, in which the lightfast resist layer (16) in the protective layer (15) contained an ultraviolet absorber, the resistance value of the transparent electrode (13) changed but the change was not more than +320%. The test specimens maintained electroconductivity at least enough to be used as a touch panel.

In Examples 1 to 5, in which the test specimens had the sulfuration-resistant resist layer (17) of the protective layer (15), the resistance value of the metal wiring (14) changed but the test specimens remained electroconductive.

In Example 6, the metal wiring (14) was broken at 300 hours in the sulfuration resistance test; i.e., the desired electroconductivity was lost. The percentage change in the weight of the sulfuration-resistant resist layer (17) was +35%, indicating that this layer was highly permeable to toluene.

In Example 7, in which the value (NCO/OH) was large, the sulfuration-resistant resist layer (17) was stiff, and the obtained substrate sheet (11) was difficult to bend.

In Example 8, the protective layer (15) was composed of a lightfast resist layer (16) as a lower layer and a sulfuration-resistant resist layer (17) as an upper layer stacked on one another. In the sulfuration resistance test, the test specimen remained electroconductive and had a certain level of sulfuration resistance for 300 hours. At 500 hours, however, the metal wiring (14) was broken; i.e., the desired electroconductivity was lost.

The shapes, layer structures, raw materials, and other conditions described in the foregoing embodiment and examples can be optionally modified without departing from the gist of the present invention. For example, it is possible to use any known raw material other than those mentioned above. Such modifications are also included in the scope of the technical idea of the present invention.

### REFERENCE SIGNS LIST

11 Substrate sheet
12 Base
13 Transparent electrode
14 Metal wiring
15 Protective layer
16 Lightfast resist layer
17 Sulfuration-resistant resist layer
18 Connector junction

1. A substrate sheet comprising a transparent electrode made of an electroconductive polymer and metal wiring on a translucent base, the metal wiring connecting the transparent electrode and a connector junction, and a protective layer covering the transparent electrode and the metal wiring, wherein
the protective layer is made up of a laminate having a sulfuration-resistant resist layer configured to prevent the metal wiring from being sulfurated and a lightfast resist layer configured to absorb ultraviolet radiation stacked on one another, and the sulfuration-resistant resist layer is a polyurethane-polyurea-based plastic layer.

2. The substrate sheet according to claim 1, wherein the protective layer is a laminate having the sulfuration-resistant resist layer and the lightfast resist layer stacked in this order from a translucent base side.

3. The substrate sheet according to claim 1, wherein a polyurethane-polyurea-based plastic forming the polyurethane-polyurea-based plastic layer is a plastic that is a product of reaction and curing of a raw material with which an NCO group/OH group value of the plastic will be in a range of 1.2 to 5.5.

4. The substrate sheet according to claim 1, wherein the sulfuration-resistant resist layer is a layer having a crosslinking density higher than that of the lightfast resist layer.

5. The substrate sheet according to claim 1, wherein the lightfast resist layer is a polyurethane-based plastic layer.

6. A touch panel comprising a display unit and the substrate sheet according to claim 1 on a screen of the display unit.
